(19) United States
(12) Patent Application Publication
(10) Pub. No.: US 2008/0110488 A1
(43) Pub. Date: May 15, 2008

(54) Apparatus and methods for reducing the transmission of stress in a solar energy collection or absorption device

(75) Inventors: Benyamin Buller, Cupertino, CA (US); Tim Leong, Danville, CA (US)

Correspondence Address: Jones & Smith, LLP;Attn: Randy Smith, 2777 Allen Parkway, Suite 800, Houston, TX, 77019, US

(73) Assignee: Solyndra, Inc., a Delware Corporation, Santa Clara, CA (US)

(21) Appl. No.: 11/982,498

(22) Filed: Nov. 2, 2007

Related U.S. Application Data
(60) Provisional application No. 60/859,213, filed on Nov. 15, 2006.
(60) Provisional application No. 60/859,212, filed on Nov. 15, 2006.
(60) Provisional application No. 60/859,188, filed on Nov. 15, 2006.
(60) Provisional application No. 60/859,033, filed on Nov. 15, 2006.
(60) Provisional application No. 60/859,215, filed on Nov. 15, 2006.
(60) Provisional application No. 60/861,162, filed on Nov. 27, 2006.
(60) Provisional application No. 60/901,517, filed on Feb. 14, 2007.

(51) Int. Cl. H01L 31/042; H01R 9/24

(52) U.S. Cl. 136/244; 439/884

(57) ABSTRACT

In some embodiments, an apparatus for reducing the transmission of stress to at least one among a plurality of photovoltaic modules mounted within a solar energy collection or absorption device includes a first electrically conductive line extending between and electrically connected to at least first and second photovoltaic modules and being capable of yielding in response to stress placed upon it.

This application claims priority to U.S. provisional application Ser. Nos. 60/859,213, 60/859,212, 60/859,188, 60/859,033, 60/859,215, 60/861,162, 60/901,517, and incorporates the preceding applications by reference herein in their entireties.

### BACKGROUND

This disclosure relates to photovoltaic energy absorption/collection technology. In some embodiments, this disclosure relates to apparatus and methods capable of assisting in reducing stress communicated to photovoltaic cells in a solar panel.

In solar energy collection or absorption devices, such as solar panels, having photovoltaic modules, stress placed upon the photovoltaic modules could cause breakage or damage to the photovoltaic modules, associated components or one or more connections therebetween. For example, the semiconductor substrate or inner glass tube of a photovoltaic cell contained in various versions of photovoltaic modules may crack or break due to stress placed upon the module. Examples of such stresses may include displacement of one or more frame member or rail of the solar panel, such as due to bowing, bending, twisting or warping. Another example stress may be thermal expansion of a frame member or other component. Yet another example stress is displacement of one or more photovoltaic module. This potential problem may be of particular concern in devices where the photovoltaic modules are load-bearing elements. Thus, it may be desirable to reduce or eliminate the communication of stress to one or more photovoltaic modules in a solar energy collection or absorption device.

It should be understood that the above-described examples, features and/or disadvantages are provided for illustrative purposes only and are not intended to limit the scope or subject matter of the claims of this patent or any patent or patent application claiming priority hereto. Thus, none of the appended claims or claims of any related application or patent should be limited by the above discussion or construed to address, include or exclude the cited examples, features and/or disadvantages, except and only to the extent as may be expressly stated in a particular claim.

### BRIEF SUMMARY

In some embodiments, the present disclosure involves an apparatus for reducing the transmission of stress to at least one among a plurality of photovoltaic modules mounted within a solar energy collection or absorption device. The apparatus includes a first electrically conductive line extending between and electrically connecting at least first and second photovoltaic modules. The first electrically conductive line is yieldable relative to and between the first and second photovoltaic modules in response to stress placed upon it, at least reducing the transmission of stress to at least one photovoltaic module.

In various embodiments, the present disclosure involves an apparatus for reducing the transmission of stress to at least one photovoltaic module among a plurality of load-bearing, elongated, photovoltaic modules mounted within a solar panel. A first electrically conductive line extends between and electrically connects at least first and second photovoltaic modules. The first electrically conductive line is yieldable relative to and between the first and second photovoltaic modules in response to stress placed upon it, at least reducing the transmission of stress to at least one photovoltaic module.

There are embodiments of the present disclosure involving an apparatus for reducing the transmission of stress to at least one photovoltaic module among a plurality of load-bearing, elongated, photovoltaic modules mounted within a solar panel. The solar panel includes two interconnected sets of opposing rails. The apparatus includes a plurality of connectors. Each connector is associated with and yieldable relative to one of the rails of the solar panel and engageable with at least one photovoltaic module. A first electrically conductive line extends between and electrically connects at least two of the connectors. Each connector is capable of yielding in response to stress placed upon it, at least reducing the transmission of such stress to at least one photovoltaic module and/or the first electrically conductive line.

Some embodiments of the present disclosure involve an apparatus for reducing the transmission of stress to at least one photovoltaic module among a plurality of load-bearing, elongated, photovoltaic modules mounted within a solar panel. The solar panel includes two interconnected sets of opposing rails. The apparatus includes at least one insert associated with and yieldable relative to one of the rails of the solar panel and engageable with at least one photovoltaic module. A first electrically conductive line extends between and electrically connects at least two of the photovoltaic modules. Each insert is capable of yielding in response to stress placed upon it, at least reducing the transmission of such stress to at least one photovoltaic module and/or the first electrically conductive line.

Accordingly, the present disclosure includes features and advantages which are believed to enable it to advance solar energy absorption or collection technology. Characteristics and advantages of the present disclosure described above and additional features and benefits will be readily apparent to those skilled in the art upon consideration of the following detailed description of embodiments of this disclosure and referring to the accompanying drawings.

### BRIEF DESCRIPTION OF THE DRAWINGS

The following figures are part of the present specification, included for background purposes or to demonstrate certain aspects of embodiments of the present disclosure and referenced in the detailed description herein.

FIG. 1 is a perspective view of an example solar panel that includes a plurality of photovoltaic modules mounted in a frame;

FIG. 2 is a plan view of the example solar panel of FIG. 1;

FIG. 3 is a partial top view of multiple example photovoltaic modules being electrically connected in parallel by first and second electrically conductive lines;

FIG. 4A is a perspective view with partial cutaway of an example of an insert with connectors and includes an embodiment of a stress transfer reducer of the present disclosure;

FIG. 4B is an exploded view of the example of the connector shown in FIG. 4A;

FIG. 4C is a partial sectional view of the example of the connector of FIG. 4A shown engaged with an example photovoltaic module and includes another embodiment of a stress transfer reducer of the present disclosure;

FIG. 5 is a partial sectional view of another example of a connector;

FIG. 6 is a partial sectional view of yet another example of a connector;

FIG. 7 is an isolated view of still a further example of a connector;

FIG. 8 is a partial top view of multiple example photovoltaic modules being electrically connected in series by first and second electrically conductive lines and includes an embodiment of a stress transfer reducer of the present disclosure;

FIG. 9 is an isolated view of an electrically conductive line that includes an embodiment of a stress transfer reducer of the present disclosure;

FIG. 10 is an isolated view of an electrically conductive line that includes another embodiment of a stress transfer reducer of the present disclosure; and

FIG. 11 is an isolated view of an electrically conductive line that includes yet another embodiment of a stress transfer reducer of the present disclosure.

### DETAILED DESCRIPTION

Characteristics and advantages of the present disclosure and additional features and benefits will be readily apparent to those skilled in the art upon consideration of the following detailed description and referring to the accompanying figures. It should be understood that the description herein and appended drawings are of various exemplary embodiments and are not intended to limit the appended claims or the claims of any patent or patent application claiming priority to this application. On the contrary, the intention is to cover all modifications, equivalents and alternatives falling within the spirit and scope of the claims. Many changes may be made to the particular embodiments and details disclosed herein without departing from such spirit and scope.

In the description below and appended figures, like or identical reference numerals are used to identify common or similar elements. The figures are not necessarily to scale and certain features and certain views of the figures may be shown exaggerated in scale or in schematic in the interest of clarity and conciseness. It should also be noted that reference herein and in the appended claims to components and aspects in a singular tense does not necessarily limit the present disclosure to only one such component or aspect, but should be interpreted generally to mean one or more, as may be suitable and desirable in each particular instance.

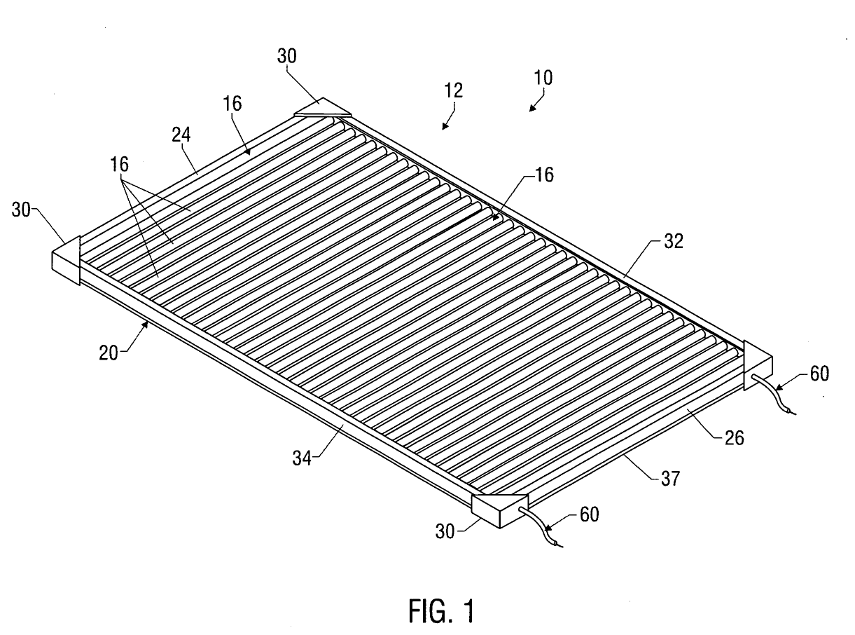

Referring initially to FIGS. 1 and 2, an example solar energy collection or absorption device 10, such as a solar panel 12, is shown having an array, or plurality, of photovoltaic cells, or modules, 16. If desired, the solar panel 12 may be used as part of a larger system of solar panels (not shown), as is and becomes further know. The photovoltaic modules 16 may have any suitable form, shape and construction. In the particular example shown, each module 16 is “elongated” because its length L (FIG. 2) is equal to or greater than three times its width, or diameter, W. However, the photovoltaic modules 16 may not be elongated and different types and configurations of photovoltaic modules 16 may be included in the same solar panel 12.

In this example, the modules 16 have a generally cylindrical overall shape with a generally circular cross-sectional shape to capture light from any direction. However, the modules 16 may have any suitable cross-sectional shape, such as square, rectangular, elliptical, polygonal, or have a varying cross-sectional shape, and any desired overall shape and configuration. For example, the modules 16 may have a cylindric-like shape, bifacial or omnifacial configuration or be otherwise designed to capture light on planes both facing and not facing the initial light source. An example omnifacial topology of a module 16 may include a bifacial configuration where both its top and bottom planes accept light and produce electric power in response to that light. Another example omnifacial topology may collect reflected light on the back and/or sides of the module 16 and light striking the module 16 from any direction other than the planar orientation of the frame 20.

The modules 16 may have any suitable construction. Each module 16 of this example includes a monolithic substrate having a plurality of solar cells (not shown) disposed or manufactured on it. In other examples, the module 16 may include a monolithic substrate having one solar cell disposed on it. In yet other examples, the module 16 may include a plurality of solar cells each made on their own individual substrates and linked together electrically.

The solar panel 12 may have any other desired components and configuration. In the example shown, the solar panel 12 includes a frame 20 having a pair of opposing first and second side rails 24, 26 interconnected with a pair of opposing first and second end rails 32, 34. The illustrated rails 24, 26, 32, 34 are each substantially straight, but, if desired, may not be straight. In this example, the rails are connected together with corner brackets 30 and the end rails 32, 34 each have a concave portion, or groove, 33. The illustrated frame 20 may employ one or more reflective or increased-albedo surface or capability, such as a backplate 37 having a reflective surface 38 located behind the modules 16, to reflect and thus redirect light back to the modules 16.

The photovoltaic modules 16 may be arranged in any desired manner and configuration. In the example shown, over three dozen photovoltaic modules 16 are secured in generally spaced parallel relationship with one another within the frame 20. However, any number of modules 16 may be contained within the solar panel 20. The illustrated modules 16 generally run perpendicular to, and extend between, the end rails 32, 34. These exemplary modules 16 are engaged in, or affixed to, the rails 32, 34 so that they in a generally fixed or rigid relationship with the frame 20 and are, thus, load bearing elements. In other configurations, one or more modules 16 may be movable. For example, the modules 16 may be engaged in, or affixed to, the rails 32, 34 so that they may be individually or collectively swiveled or tilted at angles relative to the frame 20, such as to track the movement of the sun.

The exemplary modules 16 are spaced apart and positioned depth-wise in the frame 20 so that light is capable of passing through spaces formed between the modules 16 and the modules 16 can absorb light from the direction the light emanates or reflects. For example, the modules 16 may be capable of absorbing light passing through spaces between the modules 16 and reflected back from the backplate 37. Modules 16 having a cylindrical or cylindric-like shape, or bifacial or omnifacial configuration or otherwise enabled to capture the light on a plane not facing the initial light source, may absorb light emanating or reflecting from any direction and use it to generate electrical energy.

Referring specifically to FIG. 2, each illustrated photovoltaic module 16 includes first and second electrical output contacts 42, 44 at its first and second ends 43, 45, respectively. The output contacts 42, 44 provide the electricity that is generated by the corresponding photovoltaic module 16. In this example, the first output contacts 42 are anodes and the second output contacts 44 are cathodes, but any other arrangement may be employed. Likewise, each photovoltaic module 16 may include only a single output contact or more than two output contacts at any desired location (e.g. intermediate to its ends), and the photovoltaic modules 16 need not be mounted in a frame nor capable of having an omnifacial topology (e.g. capable of absorbing light from more than one direction).

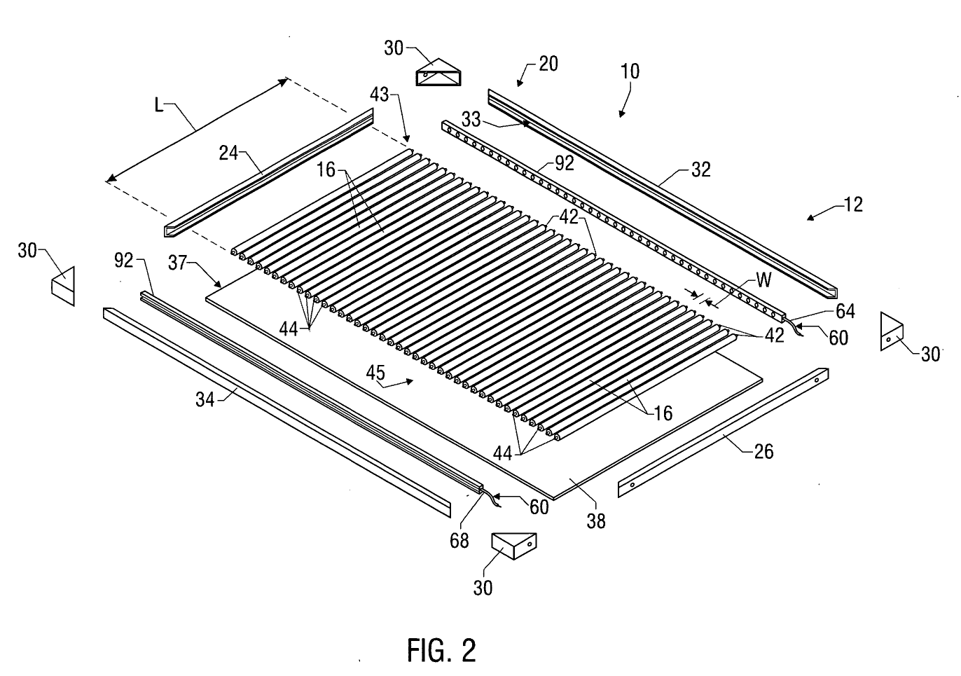

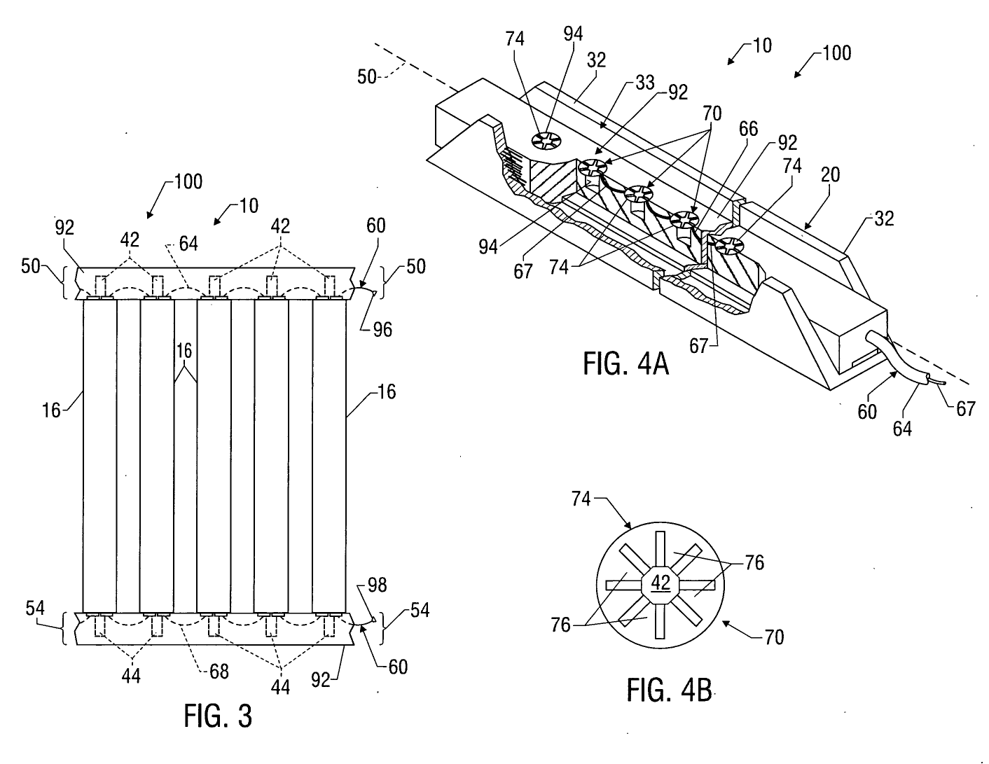

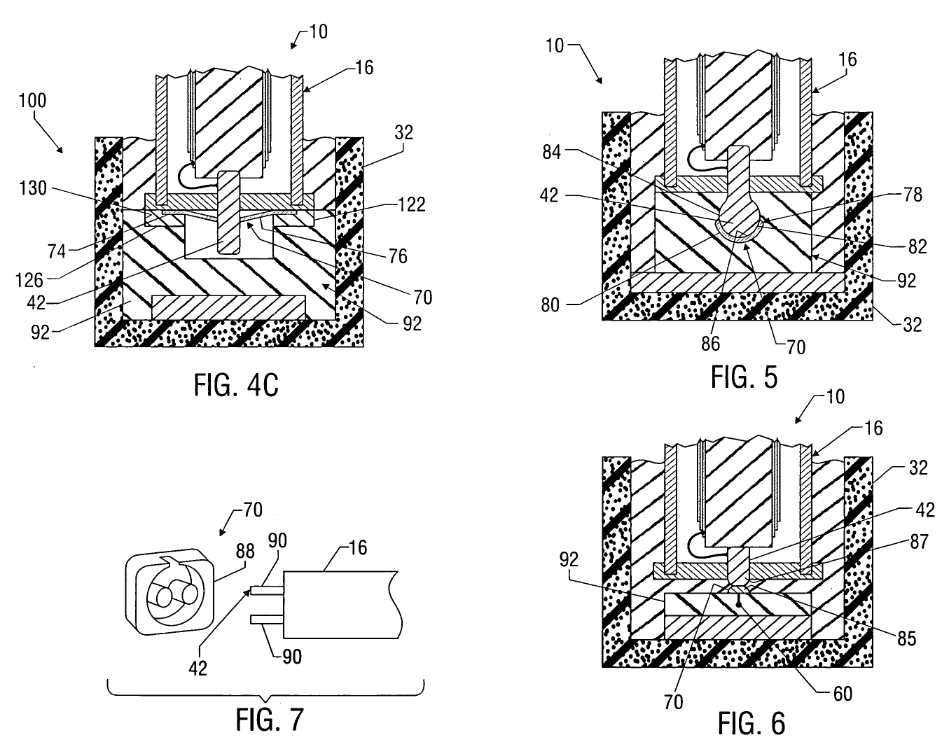

As shown in FIGS. 3 and 4, all of the first output contacts 42 of this example extend at least partially on a first common axis 50, while all of the second illustrated output contacts 44 extend at least partially on a second common axis 54. As used herein and in the appended claims, the term “axis” means a line or an area having a width that is no greater than approximately one-half its length. However, in other configurations, the output contact 42, 44 may not extend on the common axes 50, 54, respectively.

Referring again to the example of FIG. 2, at least one electrically conductive line 60 is capable of electrically connecting at least some of the photovoltaic modules 16. As used herein and in the appended claims, the term “electrically conductive line” and variations thereof means any material(s) or component(s) capable of electrically joining at least two photovoltaic modules.

The electrically conductive line (ECL) 60 may have any suitable construction, and may electrically connect at least two photovoltaic modules 16 in any desired manner. For example, the ECL 60 may be a flexible or rigid metal wire or strip, or a series thereof, soldered to at least two output contacts 42. In the example of FIGS. 2 and 3, a first ECL 64 extends on the first common axis 50 along the length of and within the first end rail 32 of the frame 20. The first ECL 64 electrically couples each of the first output contacts 42. A second ECL 68 is similarly situated with respect to the second common axis 54, second end rail 34 and second output contacts 44. It should be understood that the first and second ECLs 64, 68 need not necessarily each be a single wire or strip, but may instead each include a series of electrically conducting wires, strips or other members. Further, there are configurations where the ECLs 64, 68 do not extend on the axes 50, 54, respectively.

Referring now to FIG. 4A, the first ECL 64 of this example is a bus-type connection line 66 that includes a metallic ribbon 67 extending through the length of the end rail 32. The illustrated bus-type connection line 66 electrically connects a plurality of output contact connectors 70. Each exemplary connector 70 is capable of engaging at least one output contact 42 (FIG. 3) of at least one photovoltaic module 16. The bus-type connection line 66 and connectors 70 of FIG. 4A connect all the anode contacts 42 of the modules 16 in a common line.

When included, the connectors 70 may have any suitable form and construction, and may electrically engage the ECL 60 and photovoltaic module(s) 16 in any suitable manner. For some examples, the ECL 60 and connectors 70 may be formed integrally in a single unit, or connected by weld, solder or snapping engagement. In the example shown, the illustrated row of connectors 70 are leaf members 74 having leaves 76 (e.g. FIG. 4B) that crimp or deform into engagement with an output contact 42 of a photovoltaic module 16 (e.g. FIG. 4C).

In another example, referring to FIG. 5, the connector 70 includes a receptacle 78 engageable with at least one output contact 42. In this example, the receptacle 78 includes a curved member 80 engageable with a rounded portion 82 of the output contact 42. For example, the output contact 42 may have at least one solder point 84 that engages an at least partially C-shaped portion 86 of the curved member 80. In yet another example, referring to FIG. 6, the connector 70 includes a button contact 85 engageable with a tip, or button contact, 87 of the contact 42. In still another example, referring to FIG. 7, each connector 70 may include a socket 88 (e.g. akin to the type of socket commonly used in overhead fluorescent light fixtures) that engages at least one prong 90 of at least one output contact 42.

The connectors 70 may be disposed within the solar panel 12 in any desired manner. For example, a row of connectors 70 may be integrally formed with the corresponding end rail 32, 34 as a single unitary body (not shown). For another example, a row of connectors 70 may be integrally formed in a unitary body (not shown) that is engaged with or embedded into the end rail 32, 34. In the example of FIG. 4A, the connectors 70 and the bus-type connection line 66 are located within an insert, or socket strip, 92 that is positioned within the concave portion 33 of the first end rail 32. The illustrated socket strip 92 is designed to secure the connectors 70 in the frame 20 at predetermined spacing intervals to correspond with the orientation of the electrical output contacts 42 (e.g. FIG. 3). The insert 92 and connectors 70 of this example serve to both electrically connect and mechanically hold the modules 16 in position in the frame 20.

The socket strip 92 may have any suitable form, construction and configuration. In the example of FIG. 4A, the socket strip 92 includes cavities 94 within which the connectors 70 are seated. Additional spaces (not shown) may be necessary for placement of the electrically conductive line(s) 60. In some examples, the socket strip 92 may be constructed of flexible material, such as rubber, to facilitate engagement with the corresponding end rail 32, 34, electrically insulate the ECL 60, assist in reducing stress applied to the modules 16, facilitate seating of the connectors 70 and/or their engagement with the modules 16, or any other desired purpose. In other examples, the socket strip 92 may be constructed of a rigid material, such as to provide rigidity to the end rails 32, 34, assist in maintaining the desired positioning of the modules 16, or other purpose. Likewise, the socket strip 92 may be constructed of a semi-rigid material, such as foam, or have portions of differing rigidity and flexibility.

The socket strip 92, when included, may be engaged with the solar panel 12 in any desired manner. For example, a socket strip 92 constructed at least partially of rubber or foam may be glued inside the associated end rail 32, 34. For other examples, the socket strip 92 may be press-fit, snapped or slid into the associated end rail 32, 34.

If desired, one or more mechanism may be associated with the socket strip 92, connectors 70, modules 16, rails 24, 26, 32, 34, or any combination thereof to allow the modules 16 to be moveable. For example, components may be included to automatically swivel or tilt the modules 16 to vary their angular orientation, such as to track the movement of the sun. However, the modules 16 may be configured in any position or angular relationship relative to the rails 24, 26, 32, 34, as long as they are electrically connected within, or to, at least one rail.

It should be noted that the details of construction and operation of the first ECL 64 of this example as described above and shown in FIG. 4A apply equally, as appropriate, to the second ECL 68 of this example.

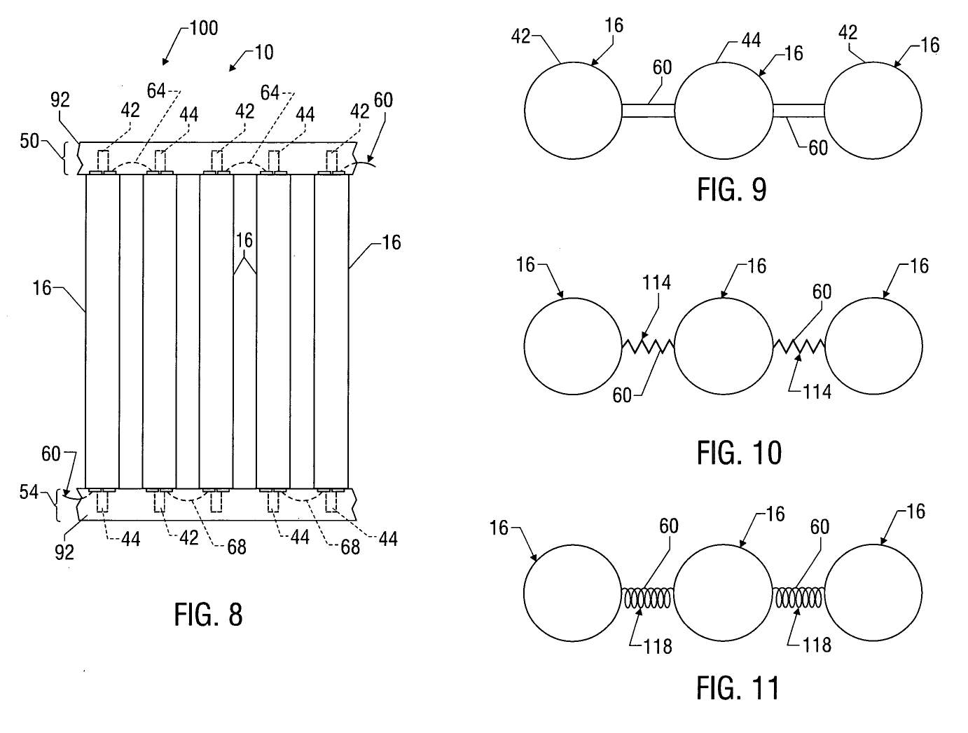

The electrical energy, or voltage, from the modules 16 may be communicated by the electrically conductive line(s) 60 from the solar panel 12 in any desired manner. In the example of FIG. 3, for example, the first ECL 64 connects all the (anode) output contacts 42 of the modules 16 to a common anode terminal 96, such as a commercially available male or female electrical plug or socket (not shown). Similarly, the second ECL 68 connects all the (cathode) output contacts 44 to a common cathode terminal 98. The illustrated modules 16 are thus connected in parallel. In this manner, the electrical connection between the modules 16 of this example is defined by two bus-like connections embedded within the framework. However, one or more electrically conductive lines 60 may be engageable in any suitable manner with any desired number of electrical output contacts of photovoltaic modules 16. For example, one ECL 60 may electrically connect some of the output contacts in the first end rail 32, while another ECL 60 electrically connects other of the output contacts in the same rail 32. For another example, such as shown in FIG. 8, the modules 16 may be arranged so that they are connected by one or more ECL 60 in series. In the example of FIG. 8, the anode contact 42 of each module 16 is positioned adjacent to and electrically connected with the cathode contact 44 of at least one adjacent module 16.

It should be understood that the present disclosure is not limited to any of the above details. Moreover, all of the above-referenced components are not required for the present disclosure, the appended claims or the claims of any patent application or patent claiming priority hereto.

Now in accordance with the present disclosure, referring to the embodiments of FIGS. 4A and 4C, the solar energy connection or absorption device 10 includes at least one stress transfer reducer 100 capable of assisting in reducing stress transferred to at least one photovoltaic module 16, damage to at least one ECL 60, separation of the connection between at least one ECL 60 and at least one module 16, or a combination thereof, due to stress placed upon or created by the device 10 or one or more components thereof. As used herein, the term “stress” and variations thereof means torsional force, bowing, twisting, bending, pulling, warping, thermal expansion, thermal contraction or the like. An example stress source is the bowing or warping of one or more rail 24, 26, 32, 34 of the frame 20 (See e.g. FIG. 1) or movement of one or more rail relative to another. Another potential stress source is the thermal expansion or bowing or other movement of one or more module 16 relative to the frame 20 or another one or more module 16 (See e.g. FIG. 1). However, the present disclosure is not limited to these example sources of stresses.

The stress transfer reducer 100 may have any suitable form and configuration as long as it assists is reducing stress transferred to at least one photovoltaic module 16, damage to at least one ECL 60, separation of the connection between at least one ECL 60 and at least one module 16, or a combination thereof. The stress transfer reducer 100 may, for example, be associated with at least one ECL 60, connector 70 or socket strip 92, a combination thereof, or other components of the device 10.

When associated with at least one ECL 60, the stress transfer reducer 100 may take any suitable form. For example, the ECL 60 may be arranged so that it is at least partially yieldable between one or more modules 16 with which it is engaged. As used herein, the term “yieldable” and variations thereof means to give way to force, pressure, etc., so as to bend, stretch, expand, contract, collapse, move or the like. The ECL 60 may be yieldable in any suitable manner, such as by changing shape when under stress, having slack or play, bending, flexing, being supple or elastic, or otherwise moving relative to the module(s) 16 to which it is connected.

In the embodiment of FIG. 4A, for example, the ECL 60 includes a non-rigid metallic ribbon 67 engageable with adjacent modules (not shown) via connectors 70. The length of the illustrated ECL 60 between each such adjacent connector 70 is greater than the distance between the adjacent connectors 70 under normal conditions without stress. Thus, in this configuration, the ribbon 67 has slack or play along its central axis between adjacent connectors 70. Sufficient clearance is provided around the ECL 60 between the adjacent connectors 70 to allow it to move. Accordingly, the tautness of the ribbon 67 can change based upon forces placed upon it. Thus, as stress is placed upon or created within the device 10, such as the frame 20, the metallic ribbon 67 may straighten, further bow or otherwise move between adjacent modules (not shown) to which it is engaged, reducing or preventing the transmission of the stress to such modules, preventing or reducing damage to the ribbon 67, breakage of its connection with the corresponding connectors 70 or a combination thereof. Likewise, if one of the modules (not shown) with which the ribbon 67 is engaged bows or otherwise moves relative to another one or more module with which the ribbon 67 is engaged, the ribbon 67 may similarly move or react. Of course, any such effect is limited by the extent of the slack in the ribbon 67, amount of stress or movement, and/or other factors.

In the embodiment of FIG. 9, the ECL 60 is simply draped across and connected, such as by spot weld or solder directly to the electrical output contact 42, 44 of the adjacent modules 16 with slack in the ECL 60 therebetween. If desired in this and other embodiments, the ECL 60 may be constructed of a strip or strand of thin conductive metal, such as copper, reducing the quantity of metal material required and potentially simplifying the manufacturing and assembly process.

In the embodiment of FIG. 10, the ECL 60 has at least one fold, such as with an accordion-like section 114, between adjacent modules 16 with which it is engaged. For example, the ECL 60 may be a conductive metal strip or strand having multiple adjacent folds that all the ECL 60 to expand and contract. In yet another example, the ECL 60 of FIG. 11 includes a coiled, spiral or helical section 118 between adjacent modules 16 so that it is spring-acting. In these and other similar configurations, the ECL 60 is capable of expanding and contracting, or otherwise yielding, in response to stress placed upon or created by the device 10 or one or more component thereof, assisting in reducing stress transferred to at least one module 16, damage to at least one ECL 60, separation of the connection between the at least one ECL 60 and at least one module 16, or a combination thereof.

Now referring to the example of FIG. 4C, in some embodiments that include connectors 70, the stress transfer reducer 100 may be associated with one or more connector 70. When associated with at least one connector 70, the stress transfer reducer 100 may take any suitable form as long as it assists is reducing stress transferred to at least one photovoltaic module 16, damage to at least one ECL 60, separation of the connection between at least one ECL 60 and at least one module 16, or a combination thereof. For example, the connector 70 may be yieldable relative to the component(s) within which it is carried, such as the end rail 32, insert 92 or other component.

In the embodiment of FIG. 4C, the connector 70 is sandwiched between the module 16 and a cushion 122. The illustrated cushion 122 is a highly pliant, elastic, foam ring 126, but may take any suitable form. The cushion 122 sits in a cut-out 130 in the insert 92 and effectively serves like a shock absorber for the connector 70 and module 16. When the end rail 32 experiences stress or the module 16 moves relative to the rail 32, the cushion 122 effectively may respond by compressing and/or expanding. The deformation of the cushion 122 allows the connector 70 to yield so that the module 16 effectively floats relative to the rail 32 and, in this example, the insert 92. Of course, the extent of yielding, floating or isolation of the connector 70 and module 16 is limited based upon the size and composition of the cushion 122, amount of stress and/or other factors.

In other embodiments, the connector(s) 70 may be spring-biased or pressure-biased (not shown) between the module 16 and the component(s) within which the connector 70 is carried, such as the end rail 32 and insert 92, providing a similar effect as described above. In other embodiments, the connector 70 may itself be constructed at least partially of cushioning, springy or other pliable material, such as rubber or foam. Any other suitable configuration having the connector 70 cushioned, biased, isolated, floating or suspended relative to the component(s) within which it is carried may likewise be used, as long as it assists is reducing stress transferred to at least one photovoltaic module 16, damage to at least one ECL 60, separation of the connection between at least one ECL 60 and at least one module 16, or a combination thereof.

Referring again to FIG. 4A, in various embodiments, the stress transfer reducer 100 may be associated with the insert, socket strip, 92 or other carrier (not shown) that anchors, or connects to, the modules 16. When associated with the insert(s) 92 or other carrier, the stress transfer reducer 100 may take any suitable form, as long as it assists is reducing stress transferred to at least one photovoltaic module 16, damage to at least one ECL 60, separation of the connection between at least one ECL 60 and at least one module 16, or a combination thereof. For example, the insert 92 may be yieldable, flexible, pliant, elastic or suitably movable within the end rail 32. In the embodiment of FIG. 4A, the insert 92 may be constructed at least partially of a pliant or bendable material, such as foam or rubber, so that when the end rail 32 experiences stress, or a module (not shown) moves relative to the rail 32, the insert 92 may compress and/or expand. In such configuration, the insert 92 thus serves as a cushion for the modules 16, allowing the modules 16 to effectively float, to some extent, relative to the rail 32 and isolating the modules 16 from at least some of the stress.

In other embodiments, the insert 92 may be cushioned, spring-biased or pressure-biased (not shown) against the end rail 32 or other component(s) within which it is carried, providing a similar effect as described above. Thus, any suitable configuration having the insert 92 or like component(s) cushioned, biased, isolated, floating or suspended relative to the component(s) within which it is carried may be used, as long as it assists is reducing stress transferred to at least one photovoltaic module 16, damage to at least one ECL 60, separation of the connection between at least one ECL 60 and at least one module 16, or a combination thereof.

Examples of the present disclosure thus offer advantages over the prior art. However, each of the appended claims does not require each of the components and acts described above and is in no way limited to the above-described examples and methods of assembly and operation. Any one or more of the above components, features and processes may be employed in any suitable configuration without inclusion of other such components, features and processes. Moreover, the present disclosure includes additional features, capabilities, functions, methods, uses and applications that have not been specifically addressed herein but are, or will become, apparent from the description herein, the appended drawings and claims.

The methods described above and which may be claimed herein and any other methods which may fall within the scope of the appended claims can be performed in any desired suitable order and are not necessarily limited to the sequence described herein or as may be listed in any appended claims. Further, the methods of the present disclosure do not necessarily require use of the particular examples shown and described in the present specification, but are equally applicable with any other suitable structure, form and configuration of components.

While examples have been shown and described, many variations, modifications and/or changes of the system, apparatus and methods herein, such as in the components, details of construction and operation, arrangement of parts and/or methods of use, are possible, contemplated by the patent applicant(s), within the scope of the appended claims, and may be made and used by one of ordinary skill in the art without departing from the spirit or teachings of this disclosure and scope of the appended claims. Thus, all matter herein set forth or shown in the accompanying drawings should be interpreted as illustrative, and the scope of this disclosure and the appended claims should not be limited to the examples described and shown herein.

1. An apparatus for reducing the transmission of stress to at least one among a plurality of photovoltaic modules mounted within a solar energy collection or absorption device, the apparatus comprising:
a first electrically conductive line extending between and electrically connected to at least first and second photovoltaic modules, said first electrically conductive line being yieldable relative to and between the first and second photovoltaic modules,
whereby said first electrically conductive line is capable of yielding in response to stress placed upon said first electrically conductive line, at least reducing the transmission of stress to at least one photovoltaic module.

2. The apparatus of claim 1 wherein the length of said first electrically conductive line between the first and second photovoltaic modules is greater than the distance between the first and second photovoltaic modules, whereby the tautness of said first electrically conductive line is variable.

3. The apparatus of claim 2 wherein each of the first and second photovoltaic modules includes at least one output contact, wherein said first electrically conductive line includes at least one flexible strip of metal engaged with at least one output contact of each of the first and second photovoltaic modules.

4. The apparatus of claim 3 wherein said first electrically conductive line includes at least one flexible strip of metal engaged, by at least one among at least one tap weld and at least one solder, with at least one output contact of each of the first and second photovoltaic modules.

5. The apparatus of claim 1 wherein said at least one electrically conductive line includes at least one fold disposed between the first and second photovoltaic modules, whereby said at least one electrically conductive line is expandable and contractible between the first and second photovoltaic modules.

6. The apparatus of claim 5 wherein said at least one electrically conductive line includes an accordion-like portion disposed between the first and second photovoltaic modules.

7. The apparatus of claim 1 wherein said at least one electrically conductive line includes a spring-like portion disposed between the first and second photovoltaic modules, whereby said at least one electrically conductive line is expandable and contractible between the first and second photovoltaic modules.

8. The apparatus of claim 7 wherein said at least one electrically conductive line includes at least one coil disposed between the first and second photovoltaic modules.

9. The apparatus of claim 7 wherein said at least one electrically conductive line includes a coiled portion disposed between the first and second photovoltaic modules.

10. The apparatus of claim 7 wherein said at least one electrically conductive line includes a helical portion disposed between the first and second photovoltaic modules.

11. The apparatus of claim 7 wherein said at least one electrically conductive line includes a spiral portion disposed between the first and second photovoltaic modules.

12. The apparatus of claim 1 wherein each of the plurality of photovoltaic modules includes at least one output contact extending at least partially on a first common axis, wherein said first electrically conductive line extends at least partially along the first common axis and engages the plurality of photovoltaic modules along the first common axis.

13. The apparatus of claim 1 wherein said first electrically conductive line assists in preventing at least one among breakage of said first electrically conductive line, damage to said first electrically conductive line, damage to at least one photovoltaic module and disconnection of said first electrically conductive line with at least one photovoltaic module.

14. The apparatus of claim 1 wherein the solar energy collection or absorption device includes a frame, further including at least one connector engageable between at least one photovoltaic module and said first electrically conductive line, wherein said at least one connector is yieldable relative to the frame, whereby said at least one connector is capable of yielding in response to stress placed upon said at least one connector, at least reducing the transmission of such stress to at least one photovoltaic module.

15. The apparatus of claim 1 wherein the solar energy collection or absorption device includes a frame having first and second opposing rails interconnected with third and fourth interconnected rails, further including at least one insert disposed at least partially within the first rail and engageable with the plurality of photovoltaic modules, wherein said at least one insert is yieldable relative to the frame, whereby said at least one insert is capable of yielding in response to stress placed upon said at least one insert, at least reducing the transmission of such stress to at least one photovoltaic module.

16. An apparatus for reducing the transmission of stress to at least one photovoltaic module among a plurality of load-bearing, elongated, photovoltaic modules mounted within a solar panel, the apparatus comprising:
a first electrically conductive line extending between and electrically connected to a plurality of the photovoltaic modules, said first electrically conductive line being yieldable relative to and between adjacent photovoltaic modules to which said first electrically conductive is connected, whereby said first electrically conductive line is capable of yielding in response to stress placed upon said first electrically conductive line, at least reducing the transmission of stress to at least one photovoltaic module.

17. The apparatus of claim 16 wherein each of the plurality of photovoltaic modules includes at least one output contact extending at least partially on a first common axis, wherein said first electrically conductive line extends at least partially along the first common axis and engages the plurality of photovoltaic modules along the first common axis.

18. The apparatus of claim 17 wherein the solar panel includes a first at least substantially straight member, wherein at least one output contact of each of the plurality of photovoltaic modules, the first common axis and said first electrically conductive line extend at least partially along the length of and within the first at least substantially straight member.

19. The apparatus of claim 17 wherein the length of said first electrically conductive between adjacent photovoltaic modules to which said first electrically conductive is connected is greater than the distance between such photovoltaic modules, whereby the tautness of said first electrically conductive line is variable.

20. The apparatus of claim 17 wherein said at least one electrically conductive line includes at least one fold disposed between adjacent photovoltaic modules to which said first electrically conductive is connected, whereby said at least one electrically conductive line is expandable and contractible between such photovoltaic modules.

21. The apparatus of claim 17 wherein said at least one electrically conductive line includes a spring-like portion disposed between adjacent photovoltaic modules to which said first electrically conductive is connected, whereby said at least one electrically conductive line is expandable and contractible between such photovoltaic modules.

22. An apparatus for reducing the transmission of stress to at least one photovoltaic module among a plurality of load-bearing, elongated, photovoltaic modules mounted within a solar panel, the solar panel including two interconnected sets of opposing rails, the apparatus comprising:
a plurality of connectors, each said connector being associated with and yieldable relative to one of the rails of the solar panel and engageable with at least one photovoltaic module; and
a first electrically conductive line extending between and electrically connecting at least two said connectors,
whereby each said connector is capable of yielding in response to stress placed upon said connector, at least reducing the transmission of such stress to at least one among at least one photovoltaic module and said first electrically conductive line.

23. The apparatus of claim 22 wherein at least one said connector is at least partially constructed of material that is at least one among pliant, bendable, flexible, elastic and springy.

24. An apparatus for reducing the transmission of stress to at least one photovoltaic module among a plurality of load-bearing, elongated, photovoltaic modules mounted within a solar panel, the solar panel including two interconnected sets of opposing rails, the apparatus comprising:
at least one insert associated with and yieldable relative to one of the rails of the solar panel and engageable with at least one photovoltaic module; and
a first electrically conductive line extending between and electrically connecting at least two of the photovoltaic modules,
whereby said at least one insert is capable of yielding in response to stress placed upon said at least one insert, at least reducing the transmission of such stress to at least one among at least one photovoltaic module and said first electrically conductive line.

25. The apparatus of claim 24 wherein said at least one insert is at least partially constructed of material that is at least one among pliant, bendable, flexible, elastic and springy.
